(19) United States
(12) Patent Application Publication
(10) Pub. No.: US 2009/0229753 A1
(43) Pub. Date: Sep. 17, 2009

(54) METHOD FOR MANUFACTURING SHOWER PLATE, SHOWER PLATE MANUFACTURED USING THE METHOD, AND PLASMA PROCESSING APPARATUS INCLUDING THE SHOWER PLATE

(75) Inventors: Tadahiro OHMI, Sendai City (JP); Tetsuya GOTO, Sendai City (JP); Kiyotaka ISHIBASHI, Amagasaki City (JP)

Correspondence Address: CANTOR COLBURN, LLP, 20 Church Street, 22nd Floor, Hartford, CT, 06103, US

(73) Assignees: TOKYO ELECTRON LIMITED, Tokyo (JP); TOHOKU UNIVERSITY, Sendai City (JP)

(21) Appl. No.: 12/402,832

(22) Filed: Mar. 12, 2009

(30) Foreign Application Priority Data
Mar. 12, 2008 (JP) 2008-063341

(51) Int. Cl. H01L 21/306; C04B 35/64; C23C 16/00

(52) U.S. Cl. 156/345.34; 264/642; 118/715

(57) ABSTRACT

A gas-communicating body 11 having a pillar shape and pores communicated with each other in a gas-communicating direction is formed. A dense member 12 is formed of a material that is not gas-permeable, has a tube shape, and covers a lateral side of the gas-communicating body 11 so that the dense member and the lateral side of the gas-communicating body contact each other. A porous piece body 13 is formed by inserting the gas-communicating body into a hollow portion of the dense member, and then the porous piece body is sintered at a first temperature. A concave portion is formed on a top plate, and a gas flow path penetrating the top plate of which one end is connected to the concave portion is formed. The porous piece body is inserted into the concave portion, and then is entirely sintered at a temperature equal to or lower than the first temperature. Accordingly, the shower plate is formed.

### CROSS-REFERENCE TO RELATED PATENT APPLICATIONS

This application claims the benefit of Japanese Patent Application No. 2008-063341 filed on Mar. 12, 2008, in the Japan Patent Office, the disclosure of which is incorporated herein in its entirety by reference.

### BACKGROUND OF THE INVENTION

1. Field of the Invention

The present invention relates to a method for manufacturing a shower plate, a shower plate manufactured using the method, and a plasma processing apparatus including the shower plate.

2. Description of the Related Art

Plasma technologies have been widely used for manufacturing many semiconductor devices such as integrated circuits, liquid crystal display devices, solar cells, and so on. Such plasma technologies are used in a deposition or etching of a thin film during a semiconductor manufacturing procedure, but a highly advanced plasma process, such as an ultra-fine process, is required for manufacturing high-performance and high-functional products.

Plasma is generated by microwaves or high frequency electromagnetic waves. Specifically, a plasma processing apparatus that generates high-density plasma excited by microwaves has been proposed. In order to generate stable plasma, it is desirable not only to uniformly radiate microwaves, but also to uniformly supply a gas for exciting plasma into a processing chamber.

Typically, a shower plate including a plurality of holes for a gas discharge is used in order to uniformly supply a gas for exciting plasma into a processing chamber. However, plasma formed directly beneath the shower plate flows reverse into the holes, and thus an abnormal discharge and accumulation of gas occur to deteriorate the yield of the products.

Japanese Patent Publication No. 2007-221116 (hereinafter, referred to as Reference 1) discloses a plasma processing apparatus which can introduce a predetermined gas from, for example, a top plate, and can generate plasma without an abnormal discharge. The plasma processing apparatus of the Reference 1 comprises a processing container, a top plate that is formed of a dielectric material and is hermetically or gas-tightly attached to an opening of the container so as to transmit electromagnetic waves into the container, an electromagnetic wave transfer means for transferring electromagnetic waves for generating plasma to the processing container, and a gas transfer means for transferring a predetermined gas to the processing container, wherein the gas transfer means includes gas ejection holes formed in the top plate so as to face inside the processing container, a porous dielectric substance placed in each of the gas ejection holes, and a gas supplying system for supplying the predetermined gas to the gas ejection holes. Thus, the top plate is also used as a shower plate.

In the conventional art, a porous dielectric substance is joined to gas ejection holes of the top plate directly or by using an adhesive. However, a gap may be generated between the top plate and the porous dielectric substance due to sintering shrinkage during sintering or firing the top plate, and thus gas may leak through the gap. Amounts of gas supplied from a plurality of gas ejection holes become non-uniform because some holes have such gap and some other holes do not have such gap. Thus, plasma becomes non-uniform. Moreover, due to repeated use of the gas ejection holes, thermal stress or heat distortion may be occurred, and thus the porous dielectric substance may be partially or entirely detached from the gas ejection holes.

### SUMMARY OF THE INVENTION

To solve the above and/or other problems, the present invention provides a method for manufacturing a shower plate which can prevent generation of plasma reverse flow and can uniformly and stably supply a gas for exciting plasma. The present invention further provides a shower plate from which any part does not fall apart when used. The invention also provides a shower plate manufactured using such method, and a plasma processing apparatus comprising the shower plate.

According to an aspect of the present invention, there is provided a method for manufacturing a shower plate for introducing gas into a processing container in a plasma processing apparatus, the method comprising: forming a porous gas-communicating body having a pillar shape with a porous material; forming a dense member having a tube shape with a dense material that is not gas-permeable; forming a porous piece body by covering a lateral side of the porous gas-communicating body with the dense member so that the lateral side of the gas-communicating body and the dense member contact each other; performing a first sintering step by sintering the porous piece body at a first temperature; forming a concave portion on one of principal surfaces of a dielectric plate, which is to face plasma, wherein the dielectric plate is a main body of the shower plate; forming a gas flow path from the bottom face of the concave portion to the other of the principal surfaces of the dielectric plate; inserting the porous piece body into the concave portion; and performing a second sintering step by entirely sintering the dielectric plate after the inserting step, at a second temperature equal to or lower than the first temperature.

The method may further include pre-sintering step in which the porous gas-communicating body is sintered in advance, before the forming step of the porous piece body.

In the performing of the first sintering step, sintering conditions are selected such that a sintering shrinkage rate of the dense member is higher than a sintering shrinkage rate of the porous gas-communicating body.

The method may further include individually checking a gas-communicating amount of the porous piece body before the inserting step.

The method may further include chamfering an edge of a surface of the porous piece body contacting the bottom face of the concave portion and an edge of a lateral side of the porous piece body, before the inserting step.

The method may further include forming a gas passage connecting the gas flow path and a space of a portion cut off during the chamfering, before the inserting step.

According to another aspect of the present invention, there is provided a shower plate for a plasma processing apparatus forming plasma, the shower plate including: a dielectric plate formed of a dielectric material; a concave portion formed on one of principal surfaces of the dielectric plate facing the plasma; a gas flow path formed from the bottom face of the concave portion to the other of the principal surfaces of the dielectric plate; a porous gas-communicating body having a pillar shape, wherein the porous gas-communicating body is formed of a porous material; a dense member having a tube shape, wherein the dense member is formed of a dense material that is not gas-permeable; and a porous piece body installed in the concave portion wherein the dense member covers a side of the porous gas-communicating body being faced to the dense member so as to be integrated, wherein a gap between the porous gas-communicating body and the dense member, and a gap between the side of the concave portion and the porous piece body are smaller than a maximum pore size in the porous gas-communicating body.

The maximum pore size may be equal to or smaller than about 0.1 mm.

The porous gas-communicating body may not contact the concave portion.

According to another aspect of the present invention, there is provided a shower plate manufactured according to the method of above.

According to another aspect of the present invention, there is provided a plasma processing apparatus including the shower plate of above.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a plasma processing apparatus including a shower plate, according to an embodiment of the present invention;

FIG. 2(a) is a plan view of a shower plate seen from a plasma processing container;

FIG. 2(b) is a cross-sectional view taken along a line M-M of FIG. 2(a);

FIG. 3A is a diagram illustrating the forming of a gas-communicating body in a method for manufacturing a shower plate according to an embodiment of the present invention;

FIG. 3B is a diagram illustrating the forming of a dense member in the method for manufacturing a shower plate according to an embodiment of the present invention;

FIG. 3C is a diagram illustrating the forming of a porous piece body in the method for manufacturing a shower plate according to an embodiment of the present invention;

FIG. 3D is a diagram illustrating the processing (cutting) of a porous piece body in the method for manufacturing a shower plate according to an embodiment of the present invention;

FIG. 3E is a diagram illustrating the processing (chamfering) of a porous piece body in the method for manufacturing a shower plate according to an embodiment of the present invention;

FIG. 3F is a diagram illustrating the forming of the shower plate in the method for manufacturing a shower plate according to an embodiment of the present invention; and

FIG. 4(a) is a cross-section of a part of FIG. 2(b), and FIGS. 4(b) and 4(c) are partially enlarged diagrams of a portion surrounded by a dotted line in FIG. 4(a).

### DETAILED DESCRIPTION OF THE INVENTION

Hereinafter, the present invention will be described in detail by explaining exemplary embodiments of the invention with reference to the attached drawings. Like reference numerals in the drawings denote like elements, and thus descriptions thereof will not be repeated.

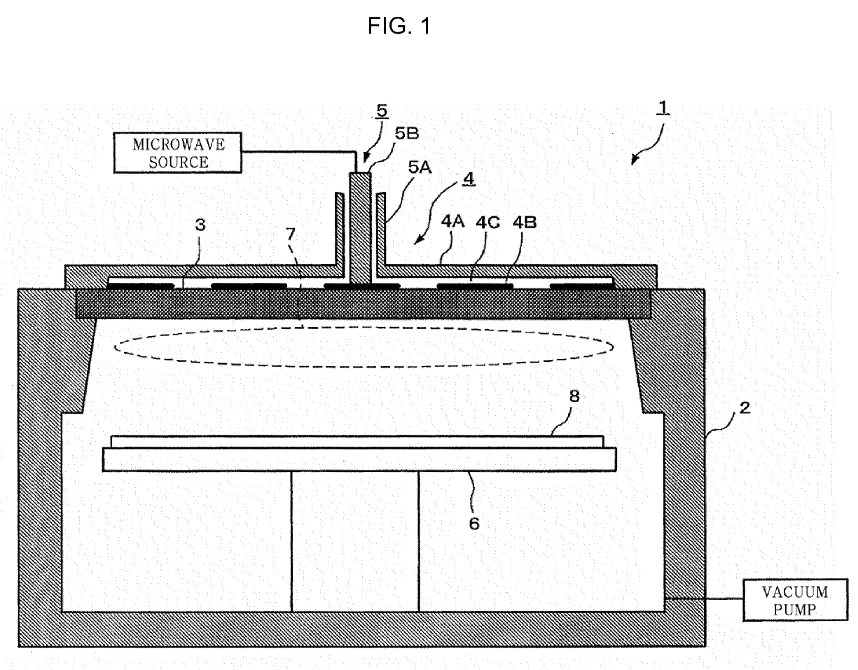

FIG. 1 is a cross-sectional view illustrating a microwave plasma processing apparatus 1 including a shower plate according to an embodiment of the present invention. The plasma processing apparatus 1 comprises a plasma processing container (chamber) 2, the shower plate (dielectric substance) 3, an antenna 4, a waveguide 5, and a substrate supporting stage 6. The antenna 4 is comprised of a waveguide portion 4A (shield member), a radial line slot antenna (RLSA) 4B, and a wavelength-shortening plate 4C (dielectric substance). The waveguide 5 is a coaxial waveguide including an external waveguide 5A and an internal waveguide 5B.

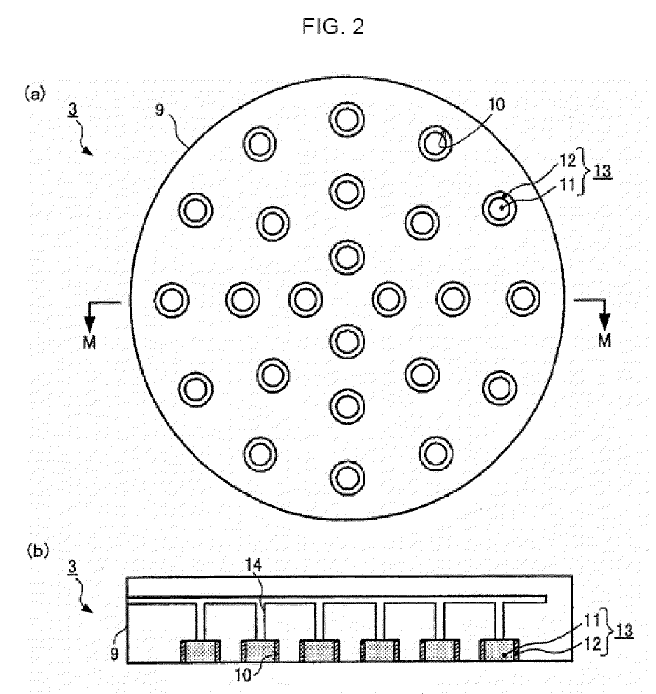

FIGS. 2(a) and 2(b) are diagrams illustrating an example of the shower plate 3 in the plasma processing apparatus 1 of FIG. 1. FIG. 2(a) is a plan view of the shower plate 3 seen from the plasma processing container 2, and FIG. 2(b) is a cross-sectional view taken along a line M-M of FIG. 2(a). The shower plate 3 is provided with a plurality of porous piece bodies 13 respectively set in a plurality of concave portions 10 of a top plate 9 (formed of a dielectric substance) that is the base material of the shower plate 3. Each of the porous piece bodies 13 is comprised of a gas-communicating body 11 and a dense member 12. The pluralities of concave portions 10 and the porous piece bodies 13 of the shower plate 3 are scattered on the top plate 9, and may be arranged in concentric circles or in alignment along a plurality of lines and it is desirable to be symmetrically arranged. Also, the shower plate 3 is provided with a gas flow path 14 penetrating the concave portion 10 from a side or top of the shower plate 3, and is capable of introducing gas into the plasma processing container 2 via the gas flow path 14.

An opening of the plasma processing container 2 of the plasma processing apparatus 1 is gas-tightly closed by the shower plate 3. Inside of the plasma processing container 2 is maintained in a vacuum state by using a vacuum pump. The antenna 4 is combined with the shower plate 3, and the waveguide 5 is connected to the antenna 4. The waveguide portion 4A is connected to the external waveguide 5A, and the RLSA 4B is combined with the internal waveguide 5B. The wavelength-shortening plate 4C is disposed between the waveguide portion 4A and the RLSA 4B, and reduces a microwave wavelength. The wavelength-shortening plate 4C may be formed of, for example, a dielectric substance such as quartz or alumina.

Microwaves are supplied from a microwave source via the waveguide 5. The microwaves then propagate between the waveguide portion 4A and the RLSA 4B in a diameter direction, and are emitted from a slot of the RLSA 4B. When plasma is formed as the microwaves are supplied inside the plasma processing container 2, inert gases such as argon (Ar) or Xenon (Xe), and nitrogen (N₂), is introduced into the plasma processing container 2. When required, a process gas, such as hydrogen, is also introduced into the plasma processing container 2.

Gas is introduced from the side or top of the shower plate 3, and is injected from the concave portion 10 via the gas flow path 14. Since the porous piece body 13 is inserted into the concave portion 10, which operates as a gas ejection hole, the gas is introduced into the plasma processing container 2 via the porous piece body 13.

The gas-communicating body 11, which is in the center of the porous piece body 13, includes a plurality of pores that are connected in a gas-communicating direction so that the gas passes therethrough. Since the porous piece body 13 is inserted into the gas ejection hole, an abnormal discharge of plasma and reverse flow of plasma are prevented. In the conventional art, when plasma is abnormally discharged, the shower plate 3 is overheated, and thus deformation or distortion due to thermal stress is occurred. Accordingly, a part of the shower plate 3 may be damaged or may fall off. However, according to the present invention, by preventing an abnormal discharge of plasma, the shower plate 3 is prevented from being damaged, and reverse flow of plasma or accumulation of gas to or in the gas ejection hole does not occur. Accordingly, it is possible to effectively generate stable plasma 7.

The dense member 12 on the circumference of the porous piece body 13 is formed of a material that is not gas-permeable. In the forming step of the porous piece body 13 by covering the side of the gas-communicating body 11 with the dense member 12, a gas-communicating amount may be individually checked. By using the shower plate 3 that includes the porous piece body 13 allowing the equal gas-communicating amount, it is possible to uniformly transfer the gas into the plasma processing container 2.

Also, by forming the dense member 12 in the porous piece body 13, the concave portion 10 and the porous piece body 13 are closely combined with each other, and the gas-communicating body 11 and the dense member 12 are also closely combined with each other. Thus, since gaps between the concave portion 10 and the porous piece body 13 and between the gas-communicating body 11 and the dense member 12 are sufficiently small, an abnormal discharge of plasma, reverse flow of plasma, and accumulation of gas are prevented, and thus the stable plasma 7 is effectively generated.

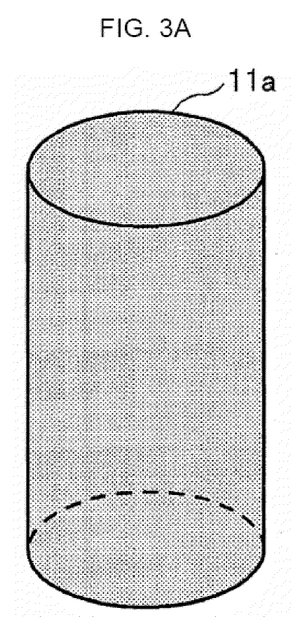

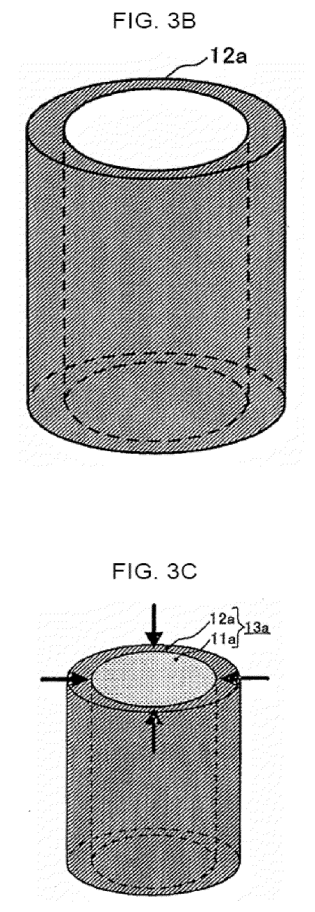

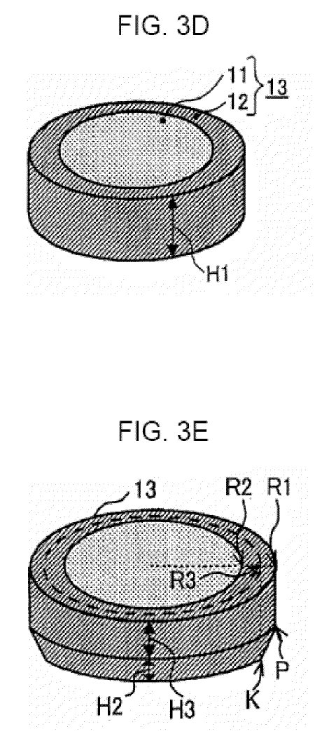

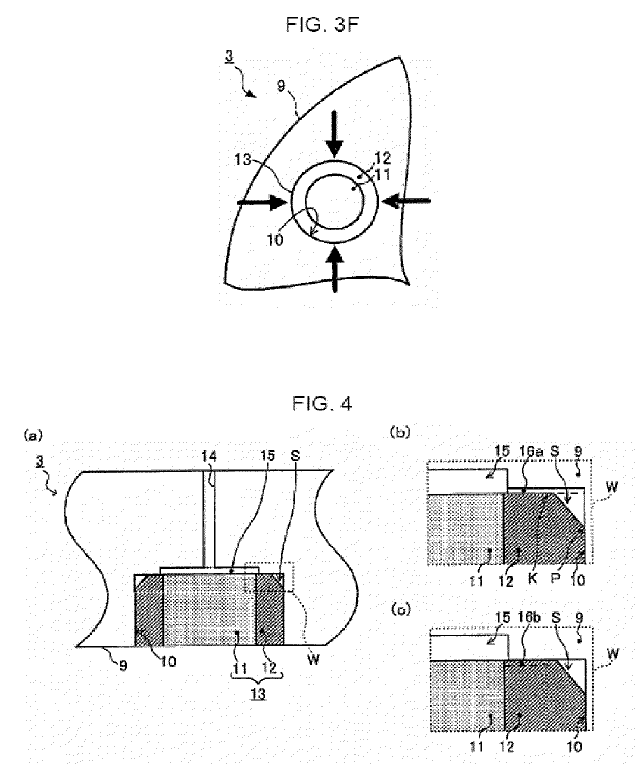

FIGS. 3A through 3F are diagrams illustrating a method for manufacturing a shower plate, according to an embodiment of the present invention. In the present embodiment, the shower plate 3 is identical to the shower plate 3 of the plasma processing apparatus 1 of FIG. 1. Specifically, FIGS. 3A through 3E illustrate processes of forming the porous piece body 13 included in the shower plate 3.

FIG. 3A is a diagram for describing forming of a gas-communicating body 11a that is made of a porous material. The gas-communicating body 11a has a pillar shape, is a member that transfers gas in a direction perpendicular to the cross-section of a circle, and has pores that are connected in a gas-communicating direction. The gas-communicating body 11a may be formed of porous quartz or porous ceramic. The maximum pore size of the pores is equal to or smaller than about 0.1 mm. When the maximum pore size is above 0.1 mm, an abnormal discharge of plasma due to microwaves may highly likely to be generated, and reverse flow of plasma may not be prevented. The pore size of the pores may be as small as possible without blocking of gas flow.

FIG. 3B is a diagram for describing forming of a dense member 12a covering a side of the gas-communicating body 11a. The dense member 12a has a tube shape and is formed of a material that is not gas-permeable. The dense member 12a may be formed of a ceramic material, such as SiO₂ or Al₂O₃. A tolerance between an inside diameter of a hollow portion of the dense member 12a and an external diameter of the gas-communicating body 11a may be referred to as a clearance fit or a transition fit.

FIG. 3C is a diagram for describing forming of a porous piece body 13a by inserting the gas-communicating body 11a into the hollow portion of the dense member 12a and sintering it. In FIG. 3C, thick arrows show portions where sintering-shrinkage is occurred in the dense member 12a during the sintering and pressure is applied from the circumference to the center of the circle. Only insertion of the dense member 12a into the gas-communicating body 11a results in generating a gap between the dense member 12a and the gas-communicating body 11a. Accordingly, by sintering a combination of the dense member 12a and the gas-communicating body 11a, the dense member 12a covering the lateral side of the gas-communicating body 11a is contracted towards the gas-communicating body 11a, and thus tightening stress is generated. As a result, the dense member 12a closely covers the lateral side of the gas-communicating body 11a.

When a gas is flowed to the porous piece body 13, if there is a gap between the gas-communicating body 11 and the dense member 12, the gas flows from the gap instead of the gas-communicating body 11, and thus gas ejection of the porous piece body 13 become non-uniform. Also, when a size of the gap is large, reverse flow or abnormal discharge of plasma may be generated, like when a pore size of the pores are large. Accordingly, the gap between the gas-communicating body 11 and the dense member 12 is set to be equal to or smaller than the maximum pore size, i.e. equal to or smaller than about 0.1 mm.

When the porous piece body 13a is sintered, the dense member 12a closely covers the lateral side of the gas-communicating body 11a if contraction of the external dense member 12a is stronger than contraction of the internal gas-communicating body 11a. The gas-communicating body 11a in FIG. 3A may be pre-sintered before the forming of the porous piece body 13a in FIG. 3C. Since it is difficult to occur the sintering-shrinkage of the gas-communicating body 11a even when the gas-communicating body 11a is subjected to sintering step for forming the porous piece body 13a, it is easier to apply a contracting pressure toward the center of the dense member 12a. Accordingly, the dense member 12a closely covers the lateral side of the gas-communicating body 11a.

A gas-communicating amount of the gas-communicating body 11 a of FIG. 3A and a gas-communicating amount of the porous piece body 13a of FIG. 3C are the same. The porous piece body 13a is formed by installing the dense member 12a on the gas-communicating body 11a, and thus non-uniformity of the external diameter remarkably decreases. Also, it becomes possible to more precisely combine the porous piece body 13 and the concave portion 10 in a post-process. Using only the gas-communicating body 11, a part of gas may flow out from the lateral side of the gas-communicating body 11 and accumulate between the concave portion 10 and the gas-communicating body 11. However by using the porous piece body 13, the dense member 12 is not penetrated by gas, and thus the gas only flows in the gas-communicating direction. Accordingly, the gas does not accumulate between the concave portion 10 and the gas-communicating body 11, and an abnormal discharge is not generated.

FIG. 3D is a diagram illustrating the porous piece body 13, wherein the integrally sintered porous piece body 13a is cut to a predetermined length. For example, when a height of the concave portion 10 is H1, the porous piece body 13 also needs to be cut to the height H1. When the porous piece body 13a is formed to have a height equal to or n times larger than H1, a plurality of porous piece bodies 13 may be formed.

FIG. 3E is a diagram for describing chamfering of the dense member 12 on one side of the porous piece body 13. An edge of a surface of the porous piece body 13 that is inserted on a lower surface of the concave portion 10 is chamfered. Actually, since the porous piece body 13 is not characterized by upper and lower directions, any side of the porous piece body 13 may be chamfered. A chamfered side is inserted into the lower surface of the concave portion 10. A diameter R1 is an external diameter of the dense member 12 and a diameter R2 is an inside diameter of the dense member 12. The height H1 of the porous piece body 13 is divided into a height H2 that is chamfered and a height H3 that is not chamfered. Since a tightening stress is applied to a side of the height H3 of the porous piece body 13 when the porous piece body 13 is installed in the concave portion 10, it is sure that the height H3 is not remarkably reduced.

A diameter of a circumference P of a lateral side of the chamfered surface of the porous piece body 13 is identical to the diameter R1. When a diameter R3 denotes a diameter of a circumference K of a lower surface of the chamfered surface of the porous piece body 13, the following inequality may be satisfied R1>R3>R2. A surface KP between the circumference K and the circumference P may be a flat surface or a curved surface.

Due to the chamfering, the lateral side of the concave portion 10 and the edge of the porous piece unit 13 are not twisted when the porous piece body 13 is inserted into the concave portion 10. Since the circumference of the lower surface of the concave portion 10 and the edge of the dense member 12 do not contact each other when the porous piece body 13 is inserted into the concave portion 10, the porous piece body 13 is prevented from coming off or being tilted. This is because sometimes the circumference may become thinner than the center of the circle or have different depths, as it is difficult to parallelize the lower surface of the concave portion 10 while forming the concave portion 10 on the top plate 9. Also, when the concave portion 10 is installed in the top plate 9, an opening of the concave portion 10 is not widened. Thus, a gap between the concave portion 10 and the porous piece body 13 is not formed.

After chamfering the porous piece body 13, a groove connecting a space S formed by chamfering and the gas flow path 14 may be formed. For example, the groove may be formed to cross the lower surface of the concave portion 10, or may be formed in a diameter direction of the dense member 12, i.e. toward the gas-communicating body 11. When the porous piece body 13 is installed, it is possible to prevent the gas from accumulating in the space S and it is easier to install the porous piece body 13.

While forming the porous piece body 13, each of gas-communicating amounts may be individually checked. Accordingly, a defective product may be pre-removed, and thus the number of defective shower plates 3 may be substantially reduced. Also, by controlling the gas-communicating amounts of the porous piece body 13, the shower plate 3 uniformly ejects gas.

FIG. 3F is a diagram for describing forming of the shower plate 3 by inserting the porous piece body 13 into the concave portion 10 of the top plate 9 and then by sintering the combination of the porous piece body 13 and the top plate 9 into a unit body. The porous piece body 13 is inserted into the concave portion 10 such a way that the chamfered surface is adjusted on the lower surface of the concave portion 10. Thick arrows in FIG. 3F show a pressure applied from the circumference of the concave portion 10 toward the center of the concave portion 10, by sintering-contracting the top plate 9 during the sintering of the shower plate 3. In other words, the pressure is applied from the top plate 9 to the porous piece body 13 inserted in the concave portion 10.

A sintering temperature while entirely sintering the shower plate 3 is equal to or lower than a sintering temperature of the porous piece body 13a of FIG. 3C. Accordingly, the porous piece body 13 is not sintering-contracted while entirely sintering the shower plate 3, and thus the size of the shower plate 3 is constant. The concave portion 10 of the top plate 9 may be adjusted according to the size of the porous piece body 13. Alternatively, the porous piece body 13 may be inserted into the concave portion 10 so that only a small gap is generated, before the sintering the shower plate 3. Alternatively, by entirely sintering the shower plate 3, the concave portion 10 tightly stresses the porous piece body 13, and thus the porous piece body 13 and the concave portion 10 are closely adhered to each other without a gap. Accordingly, it is possible to integrally fix the porous piece body 13 to the shower plate 3.

When a gap is generated between the concave portion 10 and the porous piece body 13, the gas flows from the gap, instead of the gas-communicating body 11, and thus gas ejection from the porous piece body 13 becomes non-uniform. Moreover, when the size of the gap is large, reverse flow or abnormal discharge of plasma may be generated. Accordingly, the gap between the concave portion 10 and the porous piece unit 13 may be equal to or smaller than the maximum pore size, i.e. equal to or smaller than about 0.1 mm.

Regarding a contacted portion of the concave portion 10 and the porous piece body 13, only the dense member 12 of the porous piece body 13 may contact the concave portion 10, and the gas-communicating body 11 may not contact the concave portion 10. When the gas-communicating body 11 and the concave portion 10 contact each other, a gas-communicating amount in the contacted portion may change, and thus an amount of gas that is different from a gas-communicating amount that was checked after forming the porous piece body 13 may be communicated from the porous piece body 13 inserted into the concave portion 10. Accordingly, the shower plate 3 is not able to uniformly eject the gas.

FIG. 4(a) is a cross-section of a part of the shower plate 3 of FIG. 2(b), and FIGS. 4(b) and 4(c) are partially enlarged diagrams of a portion W surrounded by a dotted line in FIG. 4(a).

FIG. 4(a) is a partially enlarged diagram of FIG. 2(b). Referring to FIG. 4(a), a surface of the porous piece body 13 is chamfered, and the chamfered surface is installed on the lower surface of the concave portion 10. Gas transferred from the gas flow path 14 is diffused via the gas-communicating body 11. When a flow path diameter of the gas flow path 14 is large, a microwave distribution changes as the electric field density changes, which causes a plasma mode to change, and thus the flow path diameter of the gas flow path 14 may become small.

A cross section of the gas flow path 14 is very small compared to a cross section of the gas-communicating body 11, and the gas flow path 14 transfers the gas only to a part of the gas-communicating body 11. Since the gas-communicating body 11 transfers the gas only in a predetermined direction, the gas is not ejected from the entire gas-communicating body 11, and thus gas ejection becomes non-uniform. Accordingly, a groove is formed in the lower surface of the concave portion 10 in order to serve as a gas diffusing space 15. A cross section of the gas diffusing space 15 is larger than the cross section of the gas-communicating body 11, and has a size that allows the lower surface of the concave portion 10 to sufficiently contact the dense member 12. When a diameter of the gas diffusing space 15 is G, the following inequality may be satisfied diameter R3 (diameter of the circumference K)>G>diameter R2 (the inner diameter of the dense member 12). The gas transferred via the gas diffusing space 15 is communicated from the entire gas-communicating body 11, and thus is uniformly ejected from the porous piece body 13. Since the gas is ejected from the plurality of the porous piece body 13, the gas is uniformly diffused just below the shower plate 3.

FIGS. 4(b) and FIG. 4(c) are enlarged diagrams of the portion W and illustrate examples of grooves 16a and 16b for preventing gas from accumulating in the space S when the porous piece body 13 is chamfered. Referring to FIG. 4(b), the groove 16a is formed to cross the lower surface of the concave portion 10. The gas accumulated in the space S flows to the gas diffusing space 15 via the groove 16a, and thus flows to the gas flow path 14. Referring to FIG. 4(c), the groove 16b is formed in a diameter direction of the dense member 12 of the porous piece body 13. The groove 16b connects the space S and the gas diffusing space 15, and transfers the gas accumulated in the space S to the gas flow path 14. The space S and the gas flow path 14 may be connected to each other via the groove 16a, the groove 16b, or any other hole for transferring the gas.

By using a shower plate manufactured using the above method, a plasma processing apparatus, which can prevent reverse flow of plasma, can uniformly and stably supply gas for exciting plasma, and prevents a part of the shower plate from falling off, may be obtained.

Materials of a top plate, a gas-communicating body, and a dense member that constitute the shower plate are not limited to the materials described above. In the embodiments of the present invention, the top plate that gas-tightly closes the plasma processing apparatus and the shower plate for introducing plasma gas are integrally formed, but the top plate and the shower plate may be separately formed. For example, a closed gas flow path is formed by combining a shower plate, in the upper surface of which a groove of a gas flow path is formed, with a top plate. A method of manufacturing a gas ejection hole has been described above. Also, a location of a porous piece body and a shape of the gas flow path of the shower plate are not limited to the above embodiments, and may have various patterns.

The plasma processing apparatus may be applied for all plasma processes, such as a plasma CVD process, an etching process, a sputtering process, and an ashing process. The plasma gas for forming plasma may be selected based on conditions such as processing methods, and a substrate for performing a plasma process is not limited to a semiconductor substrate.

By using the method of the present invention, a shower plate which can prevent reverse flow of plasma, can uniformly and stably supply gas for exciting plasma, and prevents a part thereof from falling off, is obtained.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A method for manufacturing a shower plate for introducing gas into a processing container in a plasma processing apparatus, the method comprising:
forming a porous gas-communicating body having a pillar shape with a porous material;
forming a dense member having a tube shape with a dense material that is not gas-permeable;
forming a porous piece body by covering a lateral side of the porous gas-communicating body with the dense member so that the lateral side of the gas-communicating body and the dense member contact each other;
performing a first sintering step by sintering the porous piece body at a first temperature;
forming a concave portion on one of principal surfaces of a dielectric plate, which is to face plasma, wherein the dielectric plate is a main body of the shower plate;
forming a gas flow path from the bottom face of the concave portion to the other of the principal surfaces of the dielectric plate;
inserting the porous piece body into the concave portion; and
performing a second sintering step by entirely sintering the dielectric plate after the inserting step, at a second temperature equal to or lower than the first temperature.

2. The method of claim 1, further comprising pre-sintering step in which the porous gas-communicating body is sintered in advance, before the forming step of the porous piece body.

3. The method of claim 1, wherein in the performing of the first sintering step, sintering conditions are selected such that a sintering shrinkage rate of the dense member is higher than a sintering shrinkage rate of the porous gas-communicating body.

4. The method of claim 1, further comprising individually checking a gas-communicating amount of the porous piece body before the inserting step.

5. The method of claim 1, further comprising chamfering an edge between a surface of the porous piece body contacting the bottom face of the concave portion and a lateral side of the porous piece body, before the inserting step.

6. The method of claim 5, further comprising forming a gas passage connecting the gas flow path and a space of a portion cut off during the chamfering, before the inserting step.

7. A shower plate manufactured according to the method of claim 1.

8. A plasma processing apparatus comprising the shower plate of claim 7.

9. A shower plate for a plasma processing apparatus for forming plasma, the shower plate comprising:
a dielectric plate formed of a dielectric material;
a concave portion formed on one of principal surfaces of the dielectric plate facing the plasma;
a gas flow path formed from the bottom face of the concave portion to the other of the principal surfaces of the dielectric plate;
a porous gas-communicating body having a pillar shape, wherein the porous gas-communicating body is formed of a porous material;
a dense member having a tube shape, wherein the dense member is formed of a dense material that is not gas-permeable; and
a porous piece body installed in the concave portion, wherein the dense member covers a side of the porous gas-communicating body, so as for the dense member and the side of the porous gas-communicating body to contact each other, and thus is integrated with the porous gas-communicating body,
wherein a gap between the porous gas-communicating body and the dense member, and a gap between the side of the concave portion and the porous piece body are smaller than a maximum pore size in the porous gas-communicating body.

10. The shower plate of claim 9, wherein the maximum pore size is equal to or smaller than about 0.1 mm.

11. The shower plate of claim 9, wherein the porous gas-communicating body does not contact the concave portion.

12. A plasma processing apparatus comprising the shower plate of claim 9.
